(19) United States
(12) Patent Application Publication
(10) Pub. No.: US 2020/0356014 A1
(43) Pub. Date: Nov. 12, 2020

(54) MASK TRANSFER SYSTEM AND TRANSFER METHOD

(71) Applicant: SHANGHAI MICRO ELECTRONICS EQUIPMENT (GROUP) CO., LTD., Shanghai (CN)

(72) Inventors: Gang WANG, Shanghai (CN); Dongliang HUANG, Shanghai (CN); Rongjun ZHANG, Shanghai (CN)

(21) Appl. No.: 16/640,540

(22) PCT Filed: Aug. 17, 2018
(86) PCT No.: PCT/CN2018/101173

§ 371 Date: Feb. 20, 2020

(30) Foreign Application Priority Data
Aug. 21, 2017 (CN) 201710719532.4

(51) Int. Cl. G03F 7/20; G03F 9/00

(52) U.S. Cl. CPC G03F 7/70733; G03F 9/7096

(57) ABSTRACT

A mask transfer system and transfer method, including an inner mask store (1) used for storing masks, a rotating mechanical arm used for moving the masks, and a mask fork (3) connected to the rotating mechanical arm and used for picking up the masks. The rotating mechanical arm is provided with a micro-adjustment piece (4) used for coordinating with the rotating mechanical arm to compensate position deviations of the masks picked up by the mask fork, so as to implement mask pre-alignment. The mask transfer system and transfer method achieve the effect of being low in cost.

### TECHNICAL FIELD

The present application belongs to the field of photolithography technique and relates to a mask transfer system and mask transfer methods.

### BACKGROUND

In a photolithography device, the transfer of a mask from a mask cassette to a mask stage is achieved by a mask transfer system.

Since the loading accuracy of a mask is required to be high and the mask transfer system directly interacts with the operator, a high requirement of the ergonomics is needed. During the loading or unloading process of the mask, the transfer system involves many motion positions, which requires a high transfer reliability. In particular, in the case that a mask is transferred from an internal mask storage of the photolithography device to the mask stage, the mask is placed onto the adjustment stage by a transfer mechanism, and then the adjustment stage controls its own action according to the position of the mask and adjusts the X direction, Y direction and Rz direction (i.e. the rotational direction about Z axis) of the mask to make the mask to be placed onto the mask stage in a desired position and angle. All of the above lead to a very high cost of the mask transfer system.

### SUMMARY

It is an object of the present application to provide a mask transfer system and transfer methods for solving the problem of a high cost of the mask transfer systems.

To solve the above technique problem, the present application provides a mask transfer system, comprising an internal mask storage for storing masks, a rotary manipulator for transferring masks, a mask fork connected to the rotary manipulator and configured to pick up masks, and a fine-tuning member. The fine-tuning member is configured to cooperate with the rotary manipulator to compensate for a position offset of a mask picked up by the mask fork, so as to achieve a pre-alignment of the mask.

The present application is further configured that, the rotary manipulator comprises a plurality of manipulator segments that are successively connected, and the fine-tuning member is located between two of the connected manipulator segments or between the rotary manipulator and the mask fork.

The present application is further configured that, the rotary manipulator comprises a manipulator body and a liftable lifting arm rotatably connected to the manipulator body, and the lifting arm is provided with a telescopic member.

The present application is further configured that, the telescopic member comprises a plurality of manipulator segments that are successively connected.

The present application is further configured that, a transfer mechanism is disposed at one side of the rotary manipulator and is configured to transfer a mask from an external source, and the rotary manipulator is configured to transfer the mask on the transfer mechanism into the internal mask storage.

The present application is further configured that, the mask is held in a mask cassette and the transfer mechanism is configured to transfer the mask cassette.

The present application is further configured that, the transfer mechanism comprises a guide rail inclined relative to a horizontal plane and a carrier stage in movable connection with the guide rail, the carrier stage configured to transfer the mask.

The present application is further configured that, a plurality of internal mask storages are provided.

The present application is further configured that, a distance from each of a plurality of the internal mask storages to the manipulator body is identical.

The present application is further configured that, the rotary manipulator is provided, at one side thereof, a code scanning component for scanning a code information of the mask.

The present application is further configured that, the code scanning component is also located at one side of the internal mask storage, and is configured to scan a code information of a mask in the internal mask storage.

The present application is further configured that, the mask transfer system further comprising a pre-alignment unit configured to detect X direction, Y direction and Rz direction information of the mask picked up by the mask fork and to transmit the detected information to the fine-tuning member directly or indirectly.

The present application is further configured that, the fine-tuning member is a precision rotating shaft and is configured to drive the mask fork to rotate.

The present application is further configured that, the fine-tuning member is configured to drive the mask picked up by the mask fork to perform a small scale of rotary motion.

The present application also provides a mask transfer method using an internal mask storage, a rotary manipulator, a fine-tuning member and a mask fork, wherein the rotary manipulator comprises a plurality of manipulator segments that are successively connected, the mask fork is connected to the rotary manipulator via the fine-tuning member, and the mask transfer method achieves transfer of a mask through the following steps:

S1) picking up a mask from the internal mask storage by the mask fork under a driving of the rotary manipulator;

S2) moving the mask fork to a pre-alignment unit under the driving of the rotary manipulator;

S3) detecting, by the pre-alignment unit, a position information of the mask picked up by the mask fork, and compensating, by the rotary manipulator in cooperation with the fine-tuning member, a position offset in the X direction, Y direction and Rz direction of the mask picked up by the mask fork to achieve a pre-alignment of the mask picked up by the mask fork; and

S4) conveying the mask to a mask stage by the mask fork under the driving of the rotary manipulator, after the mask picked up by the mask fork has been adjusted in the X direction, Y direction, and Rz direction.

The present application is further configured that, the fine-tuning member is a precision rotating shaft and is configured to drive the mask fork to rotate.

The present application is further configured that, the fine-tuning member is configured to drive the mask picked up by the mask fork to perform a small scale of rotary motion.

The present application is further configured that, the rotary manipulator comprises a manipulator body and a liftable lifting arm rotatably connected to the manipulator body, and the lifting arm is provided with a telescopic member.

The present application provides a mask transfer method using a transfer mechanism for transferring a mask, a rotary manipulator, a mask fork connected to the rotary manipulator and an internal mask storage, the transfer mechanism comprising a guide rail and a carrier stage in movable connection with the guide rail, the carrier stage configured to convey a mask from an external source to the rotary manipulator via a feeding port for transferring a mask, the rotary manipulator comprising manipulator segments and a fine-tuning member, wherein the mask transfer method achieves transfer of a mask through the following steps:

1) placing the mask onto the carrier stage, and moving the carrier stage to a mask transfer position under a drive of the guide rail;

2) adjusting a position of the mask fork and picking up the mask on the carrier stage by the mask fork, under a driving of the rotary manipulator and the fine-tuning member; and

3) driving, by the rotary manipulator, the mask fork to move the mask picked up by the mask fork into the internal mask storage.

The present application is further configured that, the mask transfer method further comprises step of 4): moving the carrier stage to the feeding port after picking up the mask on the carrier stage by the mask fork under the driving of the rotary manipulator.

The present application is further configured that, the rotary manipulator further comprises a manipulator body that is provided, at one side thereof, with a code scanning component.

The present application is further configured that, step 3 comprises:

31) picking up the mask by the mask fork under the driving of the rotary manipulator, so as to move the mask out of the carrier stage;

32) moving the mask picked by the mask fork under the driving of the rotary manipulator to a scanning position, where information of the mask is scanned and uploaded by the code scanning component or scanned and recorded by the code scanning component;

33) conveying, by the rotary manipulator, the mask picked up by the mask fork into the internal mask storage.

The present application is further configured that, the mask transfer method further comprises: scanning and uploading, or scanning and recording a code of the mask in the internal mask storage by the code scanning component.

Compared to the prior art, in the mask transfer system and mask transfer methods provided in the present application, during transfer of a mask, the rotary manipulator drives the mask fork to transfer the mask to the pre-alignment unit. At this moment, the rotary manipulator and the fine-tuning member receive position information of the mask and adjustment the mask the in the X, Y and Rz direction based the position information, so that the position and angle of the mask are able to meet the placement requirements. Then, the mask is pushed onto a mask stage by the rotary manipulator to complete the placement of mask. In this process, there is no necessity to configure a specific adjustment stage to regulate the mask in the X, Y and Rz direction. Therefore, the separate step of laying down the mask for adjustment and moving away the mask from the adjustment stage after the adjustment is not needed, and the transfer efficiency of the mask is thus enhanced. Moreover, since the rotary manipulator configured to transfer the mask and the fine-tuning member are able to fully adjust the mask, the overall cost is able to be cut down. Moreover, the size of the entire assembly for mask transfer and adjustments are able to be reduced, thereby allowing to set more structures such as internal mask storages, which enables to improve the efficiency of the photolithography equipment from one side and to provide a higher applicability.

### BRIEF DESCRIPTION OF THE DRAWINGS

FIG. 1 is a top view of a mask transfer system according to an embodiment of the present application.

FIG. 2 is a front view of a mask transfer system according to an embodiment of the application.

In the figures, 1—internal mask storage; 2—mask stage; 3—mask fork; 4—fine-tuning member; 5—manipulator segment; 6—manipulator body; 7—lifting arm; 8—guide rail; 9—carrier stage; 10—code scanning component; 11—pre-alignment unit.

### DETAILED DESCRIPTION

The mask transfer system and transfer methods provided in the present application will be described in greater detail below with reference to specific embodiments and accompanying drawings. Features and advantages of the application will become more apparent from the following detailed description and the appended claims. It should be noted that the accompanying drawings are provided in a very simplified form and not necessarily presented to exact scale, with the only intention to facilitate convenience and clarity in explaining the purpose of the present invention. Throughout the figures, the same or similar reference numbers represent the same or similar components.

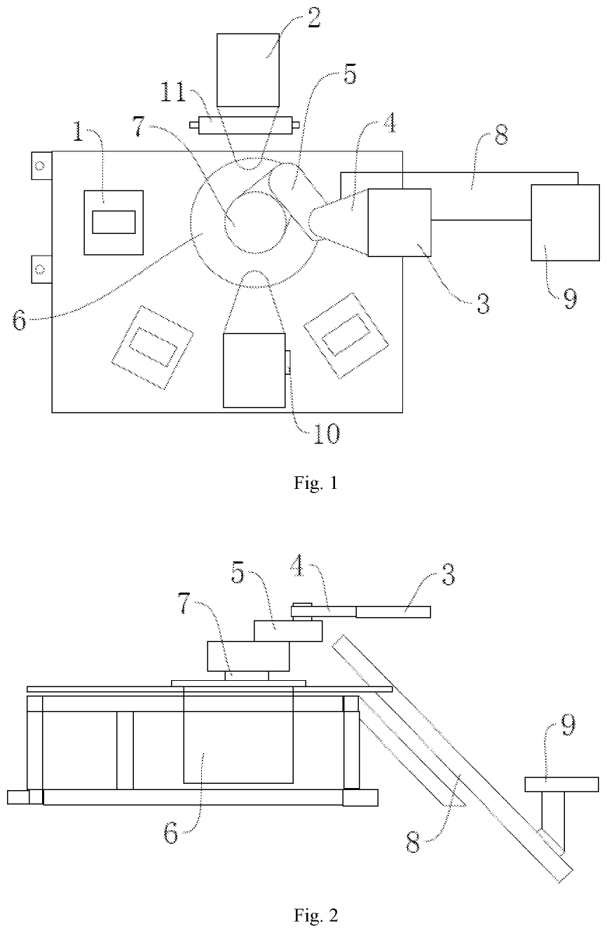

A mask transfer system includes, as shown in FIG. 1 and FIG. 2, an internal mask storage 1 for storing masks, a rotary manipulator for transferring a mask, a mask fork 3 connected to the rotary manipulator and configured to pick up a mask and a fine-tuning member 4. The fine-tuning member is configured to cooperate with the rotary manipulator to compensate for a position offset of a mask picked up by the mask fork 3, so as to achieve a pre-alignment of the mask.

According to one embodiment of present application, the rotary manipulator comprises a plurality of manipulator segments 5 that are successively connected, and the fine-tuning member 4 is located between two of the connected manipulator segments 5 or between the rotary manipulator and the mask fork 3.

According to another embodiment of present application, the rotary manipulator comprises a manipulator body 6 and a liftable lifting arm 7 rotatably connected to the manipulator body 6, and the lifting arm 7 is provided with a telescopic member. The manipulator body 6 is provided therein with a lifting shaft capable of lifting the lifting arm 7 and the mask fork 3. A rotating shaft is disposed above the lifting shaft and configured for the rotation of the telescopic member and mask fork 3. The telescopic member above the rotating shaft is configured for the telescopicity of the mask fork 3. The end of the telescopic member is provided with the fine-tuning member 4 that is used for a small scale of precision rotation of the mask fork 3. Here, the small scale of precision rotation is relative to the large scale of rotation of the mask fork 3 driven by the rotary manipulator (more specifically, the rotating shaft). Specifically, the telescopic member includes a plurality of manipulator segments 5 that are successively connected. According to this embodiment, two manipulator segments 5 are used, each of which is either both vertically and horizontally moveable or only horizontally moveable. According to this embodiment, the lifting arm 7 is vertically movable and the manipulator segments 5 are horizontally moveable. In such a way, the improved movement accuracy can be obtained.

Further, a transfer mechanism is disposed at one side of the rotary manipulator and is configured to transfer a mask from an external source, and the rotary manipulator is configured to transfer the mask on the transfer mechanism into the internal mask storage 1. The mask is held into the mask cassette and the transfer mechanism is configured to transfer the mask cassette. The transfer mechanism comprises a guide rail 8 inclined relative to the reference plane, such as the horizontal plane, ground or the mask carrying surface of the internal mask storage, and a carrier stage 9 in movable connection with the guide rail 8. The carrier stage 9 is configured to transfer the mask and the guide rail 8 may be a common cylinder slide.

Further, a plurality of internal mask storages 1 are provided. The distance from each of a plurality of the internal mask storages 1 to the manipulator body 6 may be identical or not identical. In the latter case, the movement of the manipulator segments 5 can also compensate for different distances, so that the mask can be transferred normally.

Further, the rotary manipulator may be provided, at one side thereof, a code scanning component 10 for scanning a code information of the mask. Moreover, the code scanning component 10 is also configured to scan code information of the mask into the internal mask storage. When transferring the mask, the mask fork 3 picks up the mask and moves to the code scanning position of the code scanning component 10 to scan and record code information of the mask.

Further, a pre-alignment unit is included. The pre-alignment unit detects X direction, Y direction and Rz direction information of the mask and directly or indirectly transmits the detected information to the fine-tuning member 4. The fine-tuning member 4 may be a precision rotating shaft or other precision member, and is configured to drive the mask fork 3 to perform a high precision motion in the X direction, Y direction and Rz direction.

A mask transfer method bases on the above structure and achieves a transfer of a mask on the internal mask storage 1 to the mask stage 2 through the following steps:

(S1) picking up a mask from the internal mask storage 1 by the mask fork 3 under the driving of the rotary manipulator;

(S2) moving the mask fork 3 to the pre-alignment unit 11 under the driving of the rotary manipulator;

(S3) detecting, by the pre-alignment unit 11, the position information of the mask picked up by the mask fork 3, and compensating, by the rotary manipulator in cooperation with the fine-tuning member 4, the position offset in the X direction, Y direction and Rz direction of the mask picked up by the mask fork 3 to achieve the pre-alignment procedure of the mask picked up by the mask fork 3; and

(S4) conveying the mask to the mask stage 2 by the mask fork 3 under the driving of the rotary manipulator, after the mask picked up by the mask fork 3 has been adjusted in the X direction, Y direction, and Rz direction.

The mask is transferred into the internal mask storage 1 from an external source through the following steps:

1) placing the mask onto the carrier stage 9, and moving the carrier stage 9 to the mask transfer position under the driving of the guide rail 8;

2) adjusting the position of the mask fork 3 and picking up the mask on the carrier stage 9 by the mask fork 3, under the driving of the rotary manipulator and the fine-tuning member 4;

3) driving, by the rotary manipulator, the mask fork 3 to move the mask picked up by the mask fork 3 into the internal mask storage 1; and

4) picking up the mask on the carrier stage 9 by the mask fork 3 under the driving of the rotary manipulator, and then moving the carrier stage 9 to the feeding port.

Further, the manipulator body 6 is provided, at one side thereof, with the code scanning component 10.

Further, step 3 includes:

31) picking up the mask by the mask fork 3 under the driving of the rotary manipulator, so as to move the mask out of the carrier stage 9;

32) moving the mask picked by the mask fork 3 under the driving of the rotary manipulator to a scanning position, where information of the mask is scanned and uploaded by the code scanning component 10 or scanned and recorded by the code scanning component 10;

33) conveying, by the rotary manipulator, the mask picked up by the mask fork 3 into the internal mask storage 1.

Further, the method includes step 5): scanning and uploading or recording the code of the mask in the internal mask storage 1 by the code scanning component 10.

In summary, in the mask transfer system and mask transfer methods provided in the present application, during transfer of a mask, the inclined guide rail 8 and carrier stage 9 can directly convey the mask to the rotary manipulator, thereby enabling to meet the ergonomic requirements of SEMI semiconductor manufacturing equipment in actual operational process. After the mask is conveyed to the rotary manipulator,

The rotary manipulator drives the mask fork 3 to pick up the mask and place the mask into the internal mask storage 1, while the carrier stage 9 slides down to perform the next pickup operation of mask until all of masks are placed into the internal mask storage 1. During this mask transfer process, the code scanning component 10 scans and records the code of the mask, facilitating management of the mask during the subsequent use. Or, the code scanning component 10 scans and records the code of the mask uniformly after all the masks has been placed into the internal mask storage 1, which can also be performed simultaneously with the exposure process to save the scanning time.

When a photolithography process of the mask is performed, the mask, under the driving of the mask fork 3, is moved out of the internal mask storage 1 and conveyed to the pre-alignment unit 11 of the mask stage 2. The pre-alignment unit 11 senses the mask's position and send the positional information to the rotary manipulator. Then, the rotary manipulator and the fine-tuning member 4 perform adjustments based on the specific position information of the mask to make the X direction, Y direction and Rz direction of the mask meet the placement requirements onto the mask stage 2. The mask is transfer to the mask stage 2 after completion of the adjustment, and the transfer of the mask is accomplished. Preferably, the distance from each of the mask stage 2 and a plurality of internal mask storages 1 to the manipulator body 6 is same, such that the pickup and placement of the mask can be performed easier and more precise. Moreover, since a plurality of masks are stored in the internal mask storage 1. This also allows a quicker operation in the pickup of the mask, thereby providing a higher applicability. As the pickup, storage and transfer of the mask can be accomplished only through the rotary manipulator and the guide rail 8, the input cost is able to be reduced. Further, since the mask transfer process includes few transfer operations between different components, the transfer stability of the mask becomes higher and the occupied space is reduced. The stability therefore is high.

When picking up a mask, the lifting arm 7 will rotate or move up and down and the manipulator segments 5 will rotate relative to each other, so that the position of the mask fork 3 fixed at one end of the manipulator segment 5 is adjusted until the mask fork 3 approaches the mask. At this time, fine-tuning member 4 adjusts the angle of the mask fork 3 in according to specific situation, so as to create a better adaption and combination between the mask fork 3 and the mask. The rotary manipulator continues to activate the mask fork 3 to pick up the mask. Then, the rotary manipulator acts to place the mask into internal mask storage 1 in a similar manner, and thus the transfer of the mask is completed. Each of the lifting arm 7, manipulator segments 5 and fine-tuning member 4 is able to adjust the mask's position, which allows the positional angle of the mask fork 3 to be compensated in various orientation and makes the placement of the mask in each of the X direction, Y direction and Rz direction meet requirements. In such a way, a better combination between the mask fork 3 and the mask is able to be obtained and a higher position stability of the mask in the mask transfer process is also able to be achieved.

It should be noted that, the embodiments disclosed herein are described in a progressive manner, with the description of each embodiment focusing on its differences from others. Reference can be made between the embodiments for their identical or similar parts. As for the test method disclosed in the embodiments, since the test device adopted in embodiments corresponds to the device disclosed in embodiments, the description of the test device involved therein is briefly described and the relevant parts can refer to the description of the device.

The above description merely describes a few preferred embodiments of the present invention and is not intended to limit the protection scope thereof in any sense. Any changes and modifications made by those of ordinary skilled in the art based on the above disclosure fall within the protection scope of the appended

What is claimed is:

1. A mask transfer system, comprising an internal mask store for storing masks, a rotary manipulator for transferring masks, a mask fork connected to the rotary manipulator and configured to pick up masks, and a fine-tuning member, wherein the fine-tuning member is configured to cooperate with the rotary manipulator to compensate for a position offset of a mask picked up by the mask fork, so as to achieve a pre-alignment of the mask.

2. The mask transfer system of claim 1, wherein the rotary manipulator comprises a plurality of manipulator segments that are successively connected, and the fine-tuning member is located between two of the connected manipulator segments or between the rotary manipulator and the mask fork.

3. The mask transfer system of claim 1, wherein the rotary manipulator comprises a manipulator body and a liftable lifting arm rotatably connected to the manipulator body, and the lifting and is provided with a telescopic member.

4. The mask transfer system of claim 3, wherein the telescopic member comprises a plurality of manipulator segments that are successively connected.

5. The mask transfer system of claim 1, wherein a transfer mechanism is disposed at one side of the rotary manipulator and is configured to transfer a mask from an external source, and wherein the rotary manipulator is configured to transfer the mask on the transfer mechanism into the internal mask store.

6. The mask transfer system of claim 5, wherein the mask is held in a mask cassette and the transfer mechanism is configured to transfer the mask cassette.

7. The mask transfer system of claim 5, wherein the transfer mechanism comprises a guide rail inclined relative to a horizontal plane and a carrier stage in movable connection with the guide rail, the carrier stage configured to transfer the mask.

8. The mask transfer system of claim 3, wherein a plurality of internal mask stores are provided, and a distance from each of the plurality of the internal mask stores to the manipulator body is identical or not identical.

9. (canceled)

10. The mask transfer system of claim 1, wherein the rotary manipulator is provided, at one side thereof, a code scanning component for scanning a code information of the mask.

11. The mask transfer system of claim 10, wherein the code scanning component is also located at one side of the internal mask store and is configured to scan a code information of a mask in the internal mask store.

12. The mask transfer system of claim 1, further comprising a pre-alignment unit configured to detect X direction, Y direction and Rz direction information of the mask picked up by the mask fork and to transmit the detected information to the fine-tuning member directly or indirectly.

13. The mask transfer system of claim 1, wherein the fine-tuning member is an precision rotating shaft and is configured to drive the mask fork to rotate.

14. (canceled)

15. A mask transfer method, using an internal mask store, a rotary manipulator, a fine-tuning member and a mask fork, wherein the rotary manipulator comprises a plurality of manipulator segments that are successively connected, and the mask fork is connected to the rotary manipulator via the fine-tuning member, wherein the mask transfer method achieves transfer of a mask through the following steps:
S1) picking up a mask from the internal mask store by the mask fork under a driving of the rotary manipulator;
S2) moving the mask fork to a pre-alignment unit under the driving of the rotary manipulator;
S3) detecting, by the pre-alignment unit, a position information of the mask picked up by the mask fork, and compensating, by the rotary manipulator in cooperation with the fine-tuning member, a position offset in the X direction, Y direction and Rz direction of the mask picked up by the mask fork to achieve a pre-alignment of the mask picked up by the mask fork; and
(S4) conveying the mask to a mask stage by the mask fork under the driving of the rotary manipulator, after the mask picked up by the mask fork has been adjusted in the X direction, Y direction, and Rz direction.

16. The mask transfer method of claim 15, wherein the fine-tuning member is an precision rotating shaft and is configured to drive the mask fork to rotate.

17. (canceled)

18. The mask transfer method of claim 15, wherein the rotary manipulator comprises a manipulator body and a liftable lifting arm rotatably connected to the manipulator body, and the lifting arm is provided with a telescopic member.

19. A mask transfer method, using a transfer mechanism for transferring a mask, a rotary manipulator, a mask fork connected to the rotary manipulator and an internal mask store, the transfer mechanism comprising a guide rail and a carrier stage in movable connection with the guide rail, the carrier stage configured to convey a mask from an external source to the rotary manipulator via a feeding port for transferring a mask, the rotary manipulator comprising manipulator segments and a fine-tuning member, wherein the mask transfer method achieves transfer of a mask through the following steps:
1) placing the mask onto the carrier stage, and moving the carrier stage to a mask transfer position under a driving of the guide rail;
2) adjusting a position of the mask fork and picking up the mask on the carrier stage by the mask fork, under a driving of the rotary manipulator and the fine-tuning member; and
3) driving, by the rotary manipulator, the mask fork to move the mask picked up by the mask fork into the internal mask store.

20. The mask transfer method of claim 19, further comprising a step of 4): moving the carrier stage to the feeding port after picking up the mask on the carrier stage by the mask fork under the driving of the rotary manipulator.

21. The mask transfer method of claim 19, wherein the rotary manipulator further comprises a manipulator body that is provided, at one side thereof, with a code scanning component.

22. The mask transfer method of claim 21, wherein step 3) comprises:
31) picking up the mask by the mask fork under the driving of the rotary manipulator, so as to move the mask out of the carrier stage;
32) moving the mask picked by the mask fork under the driving of the rotary manipulator to a scanning position, where information of the mask is scanned and uploaded by the code scanning component or scanned and recorded by the code scanning component;
33) conveying, by the rotary manipulator, the mask picked up by the mask fork into the internal mask store.

23. The mask transfer method of claim 21, further comprising: scanning and uploading, or scanning and recording a code of the mask in the internal mask store by the code scanning component.
